(19) United States
(12) Patent Application Publication
(10) Pub. No.: US 2016/0300764 A1
(43) Pub. Date: Oct. 13, 2016

(54) SEMICONDUCTOR DEVICE AND METHOD FOR MANUFACTURING THE SAME

(71) Applicant: HITACHI, LTD., Tokyo (JP)

(72) Inventors: Kenichi TAKEDA, Tokyo (JP); Mayu AOKI, Tokyo (JP); Kazuyuki HOZAWA, Tokyo (JP)

(21) Appl. No.: 14/903,026

(22) PCT Filed: Jul. 5, 2013
(86) PCT No.: PCT/JP2013/068511

§ 371 Date: Jan. 5, 2016

(51) Int. Cl. H01L 21/768; H01L 23/532; H01L 21/311; H01L 23/522; H01L 21/3065; H01L 23/528; H01L 23/48

(52) U.S. Cl. CPC H01L 21/76898; H01L 23/528; H01L 23/5329; H01L 23/53228; H01L 23/481; H01L 23/5226; H01L 21/76816; H01L 21/3065; H01L 21/31138; H01L 2224/16225

(57) ABSTRACT

A piece of first connecting wiring 210 is formed of a lower layer wiring close to a semiconductor element. A piece of second connecting wiring 220 is formed of an upper layer wiring far from the semiconductor element. A first opening that passes through a silicon substrate 100 and reaches the piece of first connecting wiring 210 and a second opening that passes through the silicon substrate 100 and reaches the piece of second connecting wiring 220 are formed from a back surface of the silicon substrate 100. After that, a first through silicon via 230 and a second through silicon via 240 are formed inside the first opening and the second opening, respectively. Accordingly, the first through silicon via 230 for propagating a signal, to be coupled to the piece of first connecting wiring 210, and the second through silicon via 240 for supplying a clock and a power source, to be coupled to the piece of second connecting wiring 220, can be formed. Therefore, a semiconductor device that satisfies a low parasitic resistance and a large allowable current can be achieved.

### TECHNICAL FIELD

The present invention relates to a semiconductor device having a through silicon via and a method for manufacturing the semiconductor device.

### BACKGROUND ART

Recently, a through silicon via has been used in a mounting technique of a semiconductor device.

For example, JP 2007-520051 A (PTL 1) describes a conductive via
in which a conductive layer is coated on a seed layer formed on a side wall of a hole formed through a substrate and a conductive material or a non-conductive filling material is introduced in a remaining internal space.

JP 2007-012854 A (PTL 2) describes a semiconductor chip including a first wiring pattern and a second wiring pattern that electrically couples a through via and an external connecting terminal. CITATION LIST

### Patent Literatures

PTL 1: JP 2007-520051 A

PTL 2: JP 2007-012854 A

### SUMMARY OF INVENTION

### Technical Problem

Main roles of a through silicon via in a semiconductor device include signal propagation, clock supply, and power source supply. Since a signal is directly exchanged between semiconductor elements, as a piece of connecting wiring of a through silicon via for propagating a signal, a piece of wiring of a layer close to the semiconductor elements (hereinafter, referred to as “lower layer wiring”) is preferably used. Meanwhile, since a clock and a power source require supplying without loss in a relatively wide range, as a piece of connecting wiring of a through silicon via for supplying a clock and supplying a power source, a piece of wiring of a layer that is capable of lowering wiring resistance, far from the semiconductor elements (hereinafter, referred to as “upper layer wiring”) is preferably used.

However, methods for forming through silicon vias described in the above PTLS 1 and 2 cannot form a through silicon via to be coupled to a piece of upper layer wiring and a through silicon via to be coupled to a piece of lower layer wiring.

The present invention provides a semiconductor device that satisfies a low parasitic resistance and a large allowable current by forming the through silicon via to be coupled to the piece of upper layer wiring and the through silicon via to be coupled to the piece of lower layer wiring.

### Solution to Problem

In order to solve the above problem, according to the present invention, first, a piece of first connecting wiring including a piece of lower layer wiring is formed on a main surface of a substrate and then a piece of second connecting wiring including a piece of upper layer wiring is formed. A first opening that passes through the substrate and reaches the piece of first connecting wiring and a second opening that passes through the substrate and reaches the piece of second connecting wiring, are formed from a back surface of the substrate. A first through silicon via to be coupled to the piece of first connecting wiring and a second through silicon via to be coupled to the piece of second connecting wiring are formed inside the first opening and the second opening, respectively.

### Advantageous Effects of Invention

According to the present invention, there can be provided a semiconductor device that satisfies a low parasitic resistance and a large allowable current by forming a through silicon via to be coupled to a piece of upper layer wiring and a through silicon via to be coupled to a piece of lower layer wiring.

Problems, configurations, and effects will be clarified in descriptions of the following embodiments other than the problem, the configuration, and the effect that have been described above.

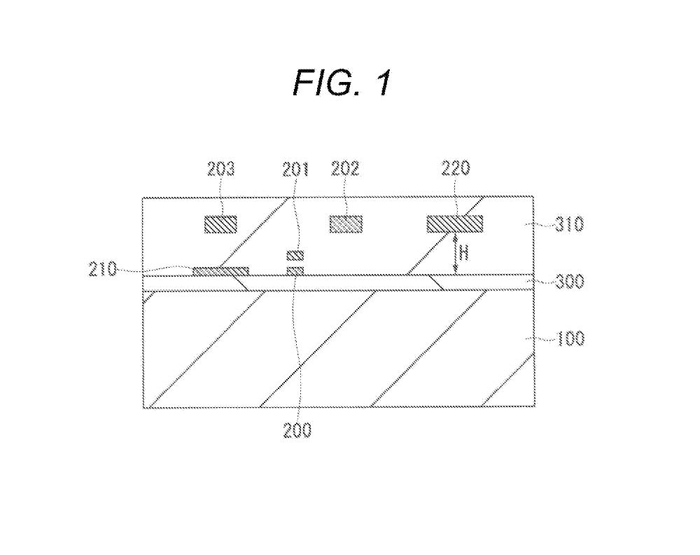

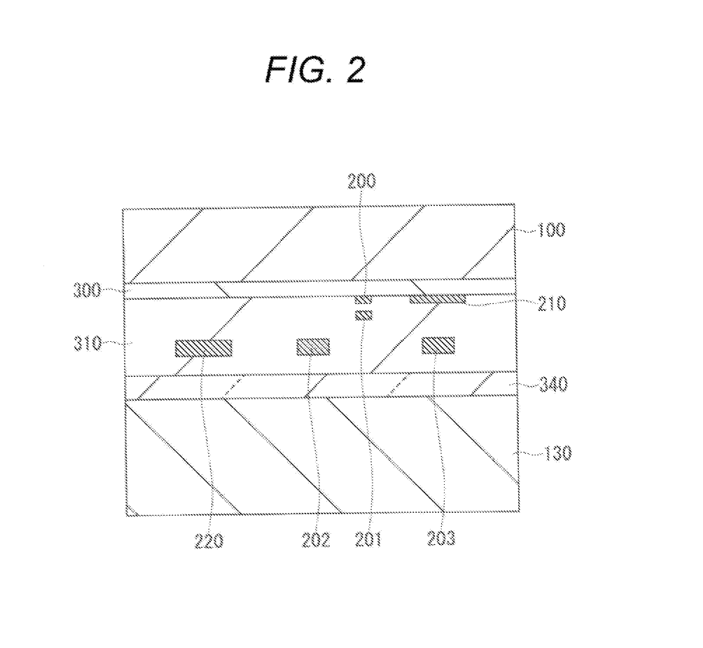

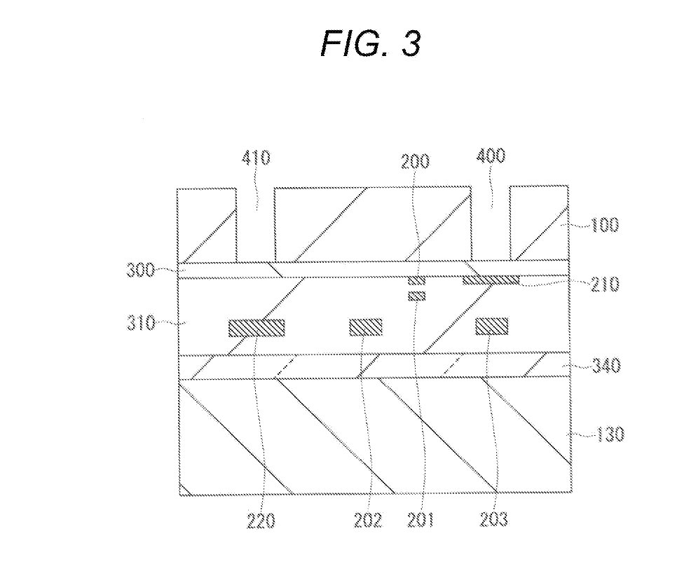

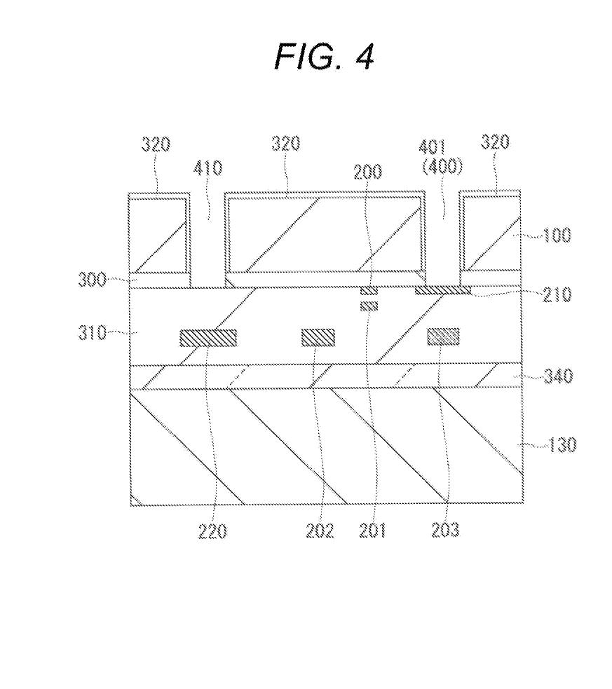

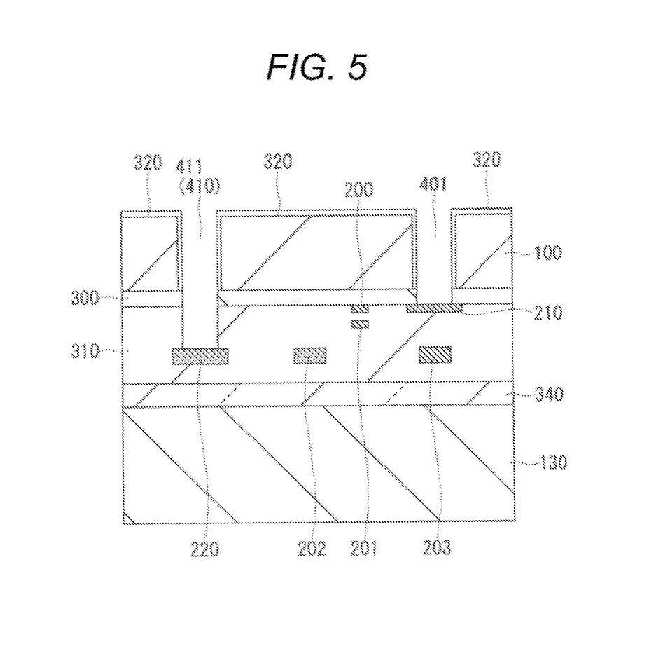

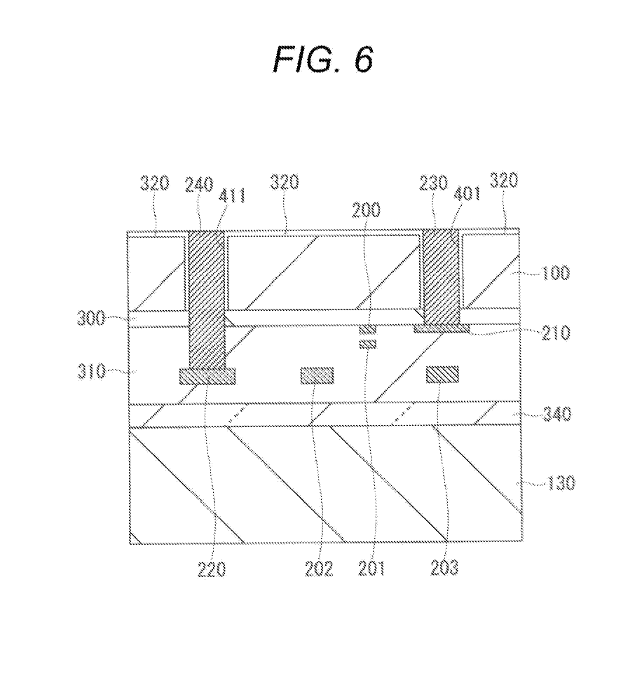

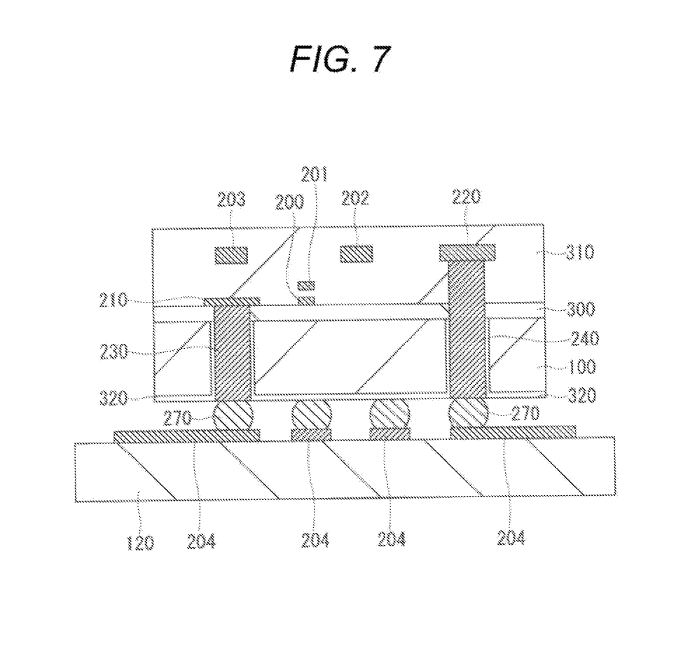

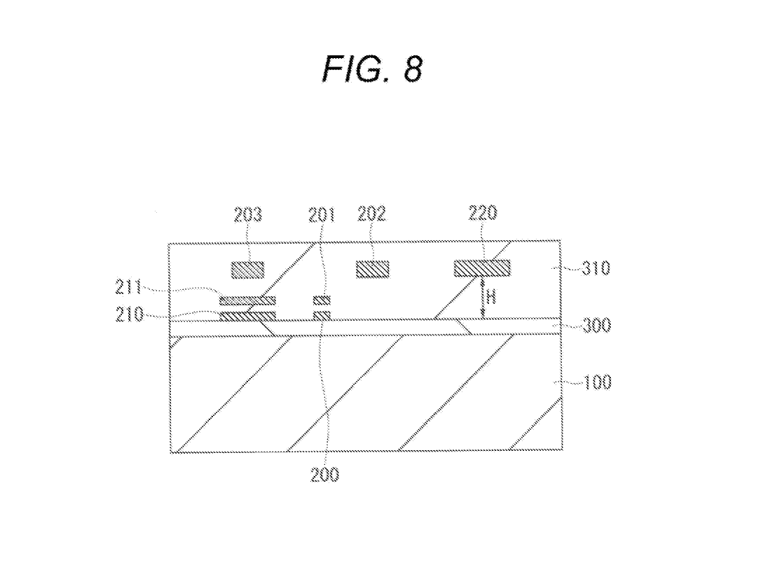

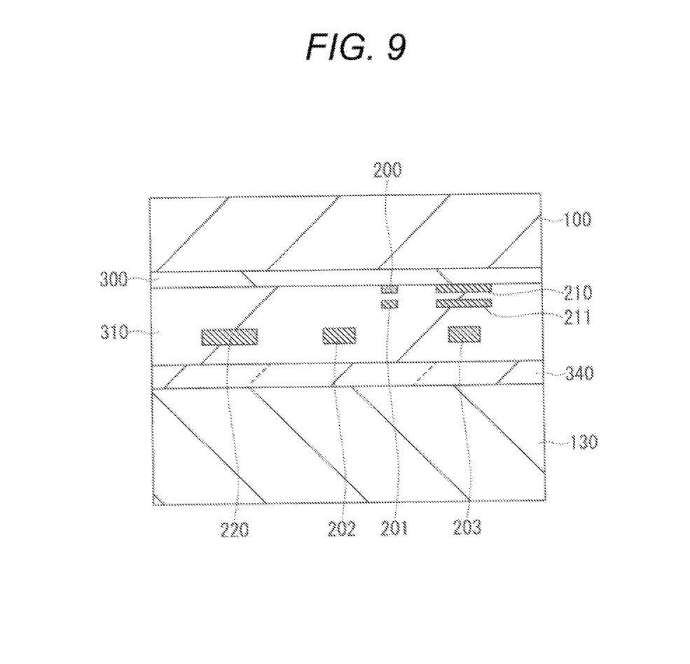

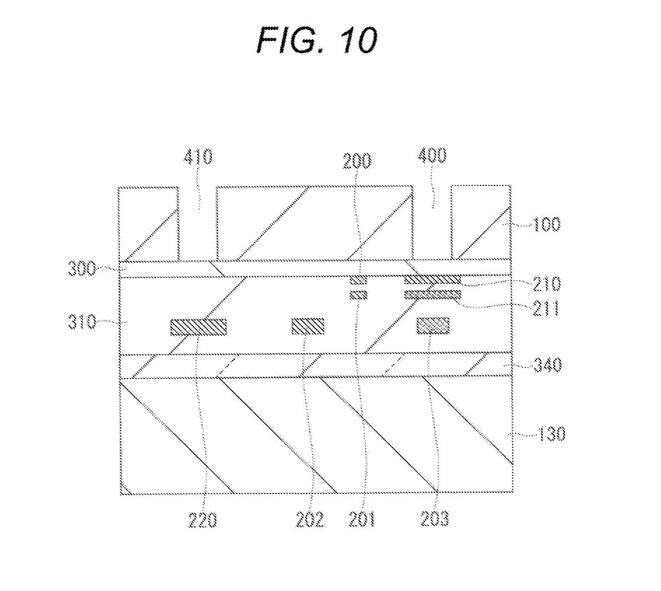

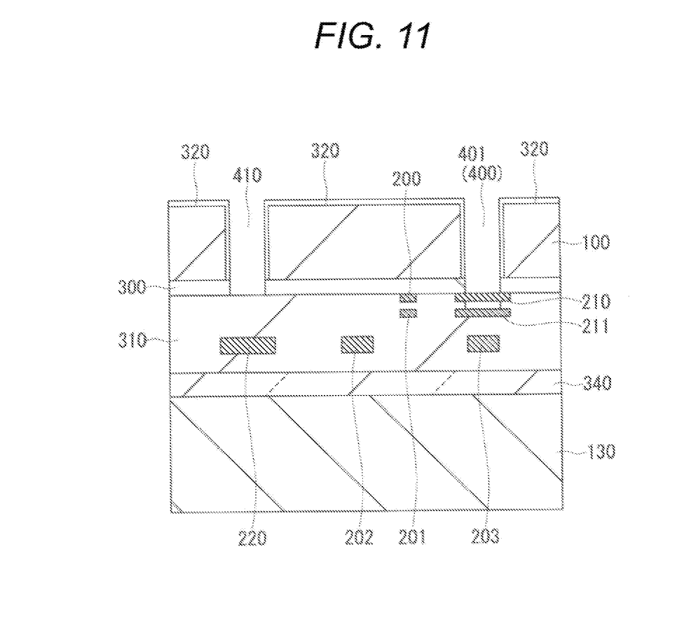

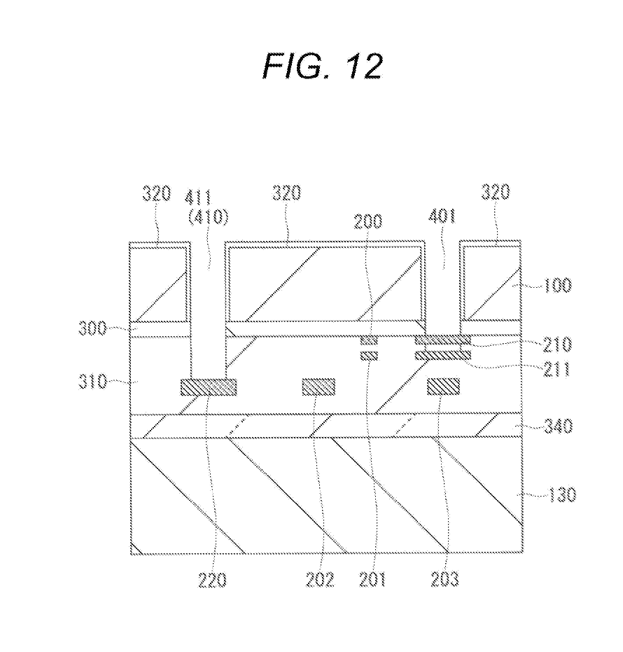

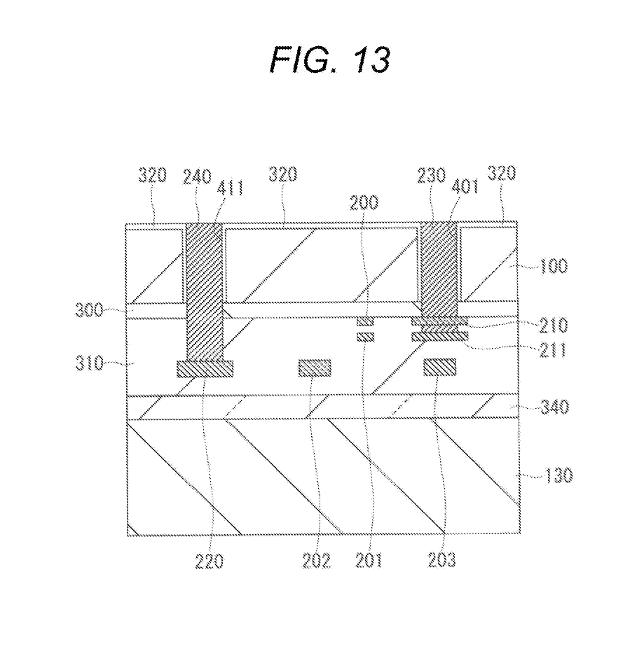

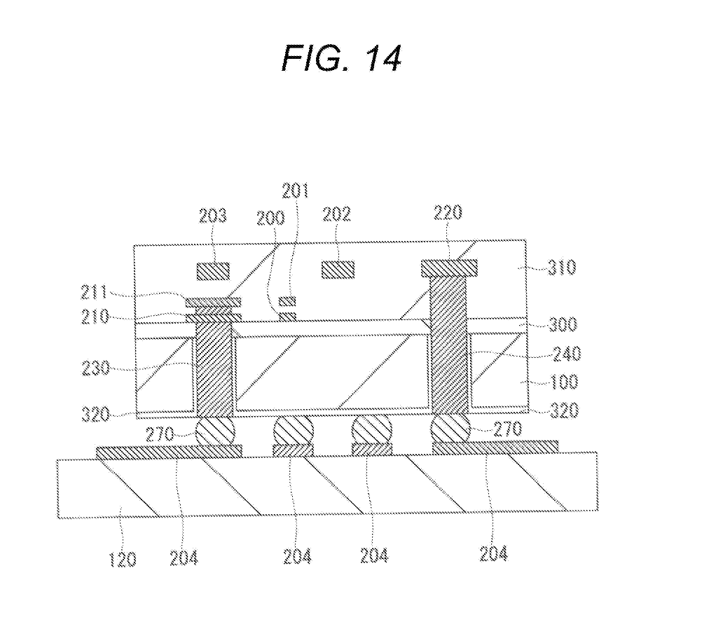

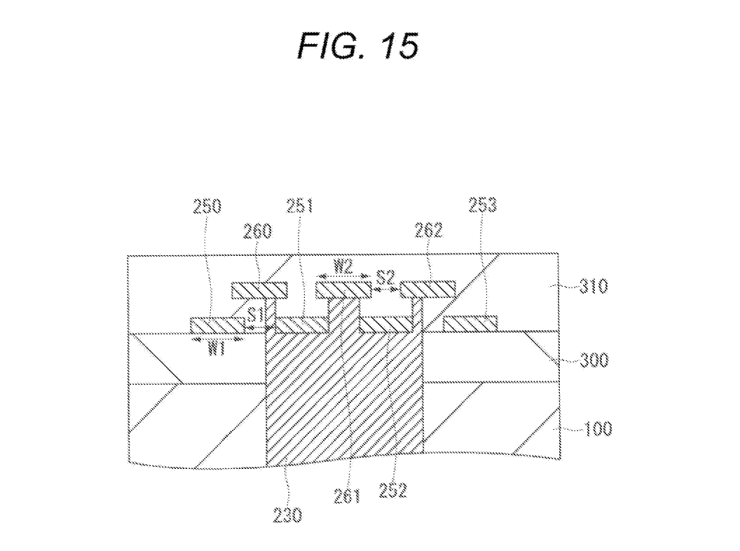

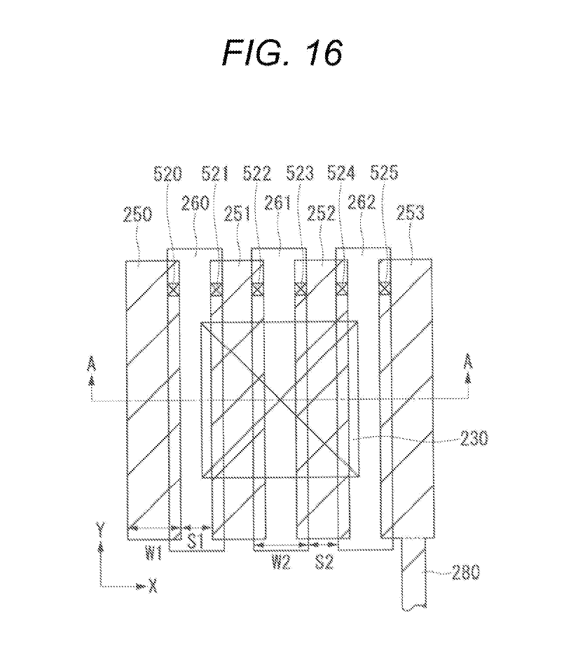

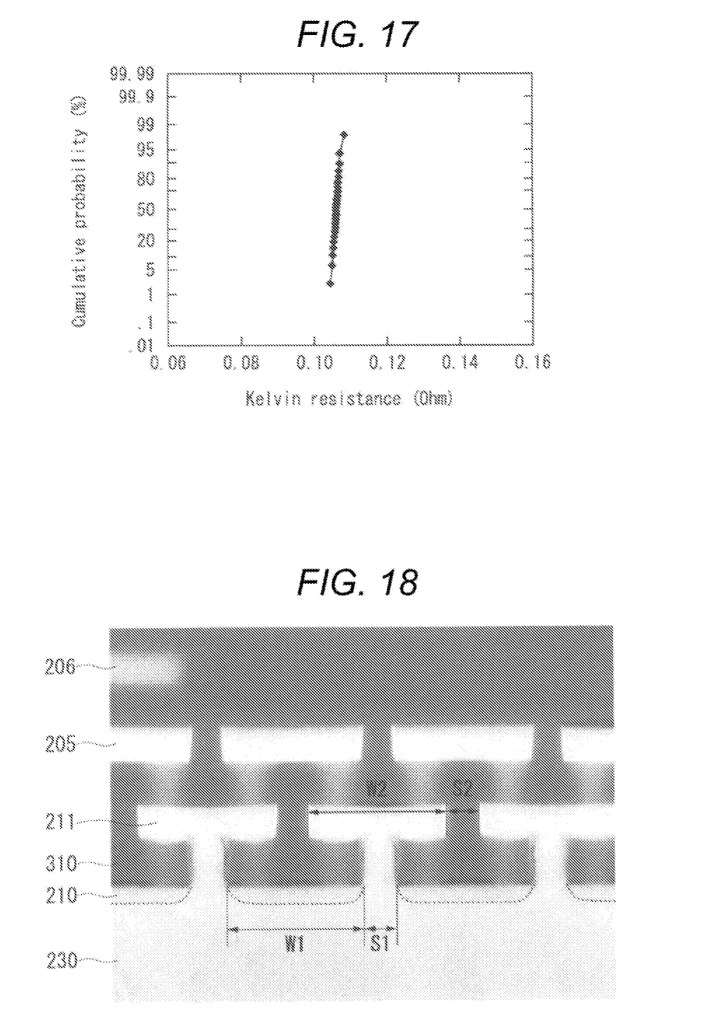

### BRIEF DESCRIPTION OF DRAWINGS

[FIG. 1] FIG. 1 is a cross-sectional view of a main portion for describing a manufacturing process of a semiconductor device according to a first embodiment.

[FIG. 2] FIG. 2 is a cross-sectional view of the same main portion in FIG. 1 during the manufacturing process of the semiconductor device, following FIG. 1.

[FIG. 3] FIG. 3 is a cross-sectional view of the same main portion in FIG. 1 during the manufacturing process of the semiconductor device, following FIG. 2.

[FIG. 4] FIG. 4 is a cross-sectional view of the same main portion in FIG. 1 during the manufacturing process of the semiconductor device, following FIG. 3.

[FIG. 5] FIG. 5 is a cross-sectional view of the same main portion in FIG. 1 during the manufacturing process of the semiconductor device, following FIG. 4.

[FIG. 6] FIG. 6 is a cross-sectional view of the same main portion in FIG. 1 during the manufacturing process of the semiconductor device, following FIG. 5.

[FIG. 7] FIG. 7 is a cross-sectional view of the same main portion in FIG. 1 during the manufacturing process of the semiconductor device, following FIG. 6.

[FIG. 8] FIG. 8 is a cross-sectional view of a main portion for describing a manufacturing process of a semiconductor device according to a second embodiment.

[FIG. 9] FIG. 9 is a cross-sectional view of the same main portion in FIG. 8 during the manufacturing process of the semiconductor device, following FIG. 8.

[FIG. 10] FIG. 10 is a cross-sectional view of the same main portion in FIG. 8 during the manufacturing process of the semiconductor device, following FIG. 9.

[FIG. 11] FIG. 11 is a cross-sectional view of the same main portion in FIG. 8 during the manufacturing process of the semiconductor device, following FIG. 10.

[FIG. 12] FIG. 12 is a cross-sectional view of the same main portion in FIG. 8 during the manufacturing process of the semiconductor device, following FIG. 11.

[FIG. 13] FIG. 13 is a cross-sectional view of the same main portion in FIG. 8 during the manufacturing process of the semiconductor device, following FIG. 12.

[FIG. 14] FIG. 14 is a cross-sectional view of the same main portion in FIG. 8 during the manufacturing process of the semiconductor device, following FIG. 13.

[FIG. 15] FIG. 15 is a partially enlarged cross-sectional view of a main portion illustrating apiece of lower layer wiring (first connecting wiring) and apart of a first through silicon via according to the second embodiment.

[FIG. 16] FIG. 16 is a partially enlarged plan view of a main portion illustrating the piece of lower layer wiring (first connecting wiring) and a part of the first through silicon via according to the second embodiment.

[FIG. 17] FIG. 17 is a graphical representation of through probability as a function of Kelvin resistance including the first through silicon via according to the second embodiment.

[FIG. 18] FIG. 18 is a photo taken by a scanning electron microscope illustrating a connecting portion between the first through silicon via and the piece of first connecting wiring according to the second embodiment.

### DESCRIPTION OF EMBODIMENTS

In the following embodiments, descriptions will be divided into a plurality of sections or embodiments so as to be given when necessary for convenience. Excluding a case where a clear indication is given, they are not mutually irrelevant. For example, one is a part, an entire modification, a detail, or an additional description of the other.

In the following embodiments, in a case where the number of elements (including, for example, a number, a value, a quantity, a range) is referred, the embodiments are not limited to the specific number and the specific number or more or the specific number or less may be applicable, excluding a case where a clear indication is specifically given and a case where the embodiments are clearly limited to the specific number in principle.

In the following embodiments, needless to say, constituent elements (including element steps) are not necessarily mandatory, excluding a case where a clear indication is specifically given and a case where the constituent elements are clearly mandatory in principle.

Referring to “including an A”, “including the A”, “having the A”, and “including the A” does not indicate that elements except the A are eliminated, needless to say, excluding a case where, in particular, it is clearly indicated that there is only the A. Similarly, in the following embodiments, when shapes, position relationships, and the like of, for example, the constitute elements are referred, a shape and the like that are substantially the same or similar to the shapes is included, excluding a case where a clear indication is specifically given and a case where contradiction is clearly made in principle. This is similarly applicable to the above value and range.

The drawings used in the following embodiments may include hatching in order to easily observe the drawings even when being plan views. In the entire drawing for describing the following embodiments, elements having the same functions are denoted with the same reference signs, and the duplicate descriptions thereof will be omitted. The present embodiments will be described in detail below based on the drawings.

### First Embodiment

### Description of Through Silicon Via in the Related Art

First, a through silicon via in the related art will be described before a through silicon via according to a first embodiment will be described.

The through silicon via has a role of supplying a clock and a power source to an entire semiconductor device other than propagation of a signal. Therefore, it is necessary that a piece of connecting wiring and the through silicon via formed in the semiconductor device are coupled and then power supplied from the through silicon via is distributed to the entire semiconductor device.

For example, the above PTL 1 describes a manufacturing process of forming a piece of connecting wiring to be coupled to a through silicon via after the through silicon via is formed by filling a metal film in an opening formed in a silicon substrate. The above PTL 2 describes a manufacturing process of forming simultaneously a first wiring pattern and a second wiring pattern by a multilayer wiring structure on the side of a front surface of a semiconductor substrate, forming a through hole that passes through only the semiconductor substrate from a back surface of the semiconductor substrate, filling a metal film into the through hole, and forming a through via to be coupled to the second wiring pattern.

As described above, since a signal is directly exchanged between semiconductor elements, a piece of lower layer wiring is preferable used for a piece of connecting wiring of a through silicon via for propagating a signal. Meanwhile, since a clock and a power source require supplying without loss in a relatively wide range, as a piece of connecting wiring of a through silicon via for supplying a clock and for supplying a power source, apiece of upper layer wiring is preferably used. However, for example, in each of the manufacturing processes described in the above PTLS 1 and 2, the piece of connecting wiring is limited to the same wiring layer.

In a case where the piece of lower layer wiring is only used for the piece of connecting wiring, it is necessary that the piece of connecting wiring and the piece of upper layer wiring be coupled through a plurality of wiring layers and connecting holes. Therefore, a parasitic resistance becomes high and then power consumption increases. Since current density that can be tolerated by one through silicon via is limited, it is necessary to increase the number of through silicon vias.

Meanwhile, in a case where the piece of upper layer wiring is only used for the piece of connecting wiring, it is necessary that the through silicon via is coupled to a semiconductor element through the piece of multilayer wiring after once the through silicon via is coupled to the piece of connecting wiring, in order to couple the piece of connecting wiring and the semiconductor element. Accordingly, a forming region of the piece of multilayer wiring that can be originally used for other uses is occupied by the piece of multilayer wiring used for connecting with the piece of connecting wiring. A wiring resource that can be used for other uses decreases and then an increase of a size of a chip or an increase of the number of wiring layers occur. In principle, for each through silicon via mutually having a different length, a through silicon via can be formed, for example, based on the method described in the above implementation PTL 2. However, the method drastically increases a manufacturing cost and is unsuitable for practical use.

### Structure of Through Silicon Via Included in Semiconductor Device and Method for Manufacturing the Structure

A semiconductor device according to the first embodiment is a semiconductor device capable of taking out electrical connection to the outside of a chip through each of through silicon vias directly coupled to a piece of upper layer wiring and a piece of lower layer wiring in the same chip.

A method for manufacturing the semiconductor device according to the first embodiment will be sequentially described by following processes with reference to FIGS. 1 to 7. FIGS. 1 to 7 are cross-sectional views of main portions illustrating the method for manufacturing the semiconductor device.

First, as illustrated in FIG. 1, a device protecting insulating film 300 including, for example, a silicon oxide is formed on a main surface of a silicon substrate (at this stage, a flat and substantially circular shaped semiconductor thin plate referred to as a “semiconductor wafer”) 100. Subsequently, for example, a sputtering method, a lithography method, an etching method, or a chemical vapor deposition (CVD) method, is used so as to form pieces of metal wiring 200, 201, 202, and 203, a piece of first connecting wiring 210, a piece of second connecting wiring 220, and a wiring interlayer insulating film 310.

Here, the piece of metal wiring 200 and the piece of first connecting wiring 210 are formed of the same wiring layer (single layer). The pieces of metal wiring 202 and 203 and the piece of second connecting wiring 220 are formed of the same wiring layer (single layer). The piece of second connecting wiring 220 is formed in a square region measuring 10 μm on a side in plan view.

The pieces of metal wiring 200, 201, 202, and 203, the piece of first connecting wiring 210, and the piece of second connecting wiring 220 include, for example, copper (Cu) as a main component. The wiring interlayer insulating film 310 includes, for example, a silicon oxide and an organic group-containing silicon oxide as main constituent materials. Copper (Cu) is lower than aluminum (Al) in terms of resistivity, and is effective in a method for reducing a wiring delay. The silicon substrate 100 is a substrate that has completed a so-called pre-process. An integrated circuit including, for example, a semiconductor element and a piece of wiring that couples the semiconductor element, are formed in a predetermined region on the main surface of the silicon substrate 100.

Note that, in FIG. 1, a part of a piece of multilayer wiring formed on the main surface of the silicon substrate 100 is only illustrated. For example, illustrations including a piece of wiring that is not directly related to the semiconductor element and the description, will be omitted. According to the first embodiment, a distance H between a base of the piece of first connecting wiring 210 and a base of the piece of second connecting wiring 220 is set to be, for example, 2.0 μm.

Next, as illustrated in FIG. 2, after an adhesive 340 is formed on a fixing substrate 130, the fixing substrate 130 and the wiring interlayer insulating film 310 formed on the side of the main surface of the silicon substrate 100 adhere to each other through the adhesive 340. After that, by using, for example, a back grinding method or a dry polishing method, a back surface of the silicon substrate 100 (surface opposite to the main surface) is ground so as to thin a thickness of the silicon substrate 100 to 50 μm. Here, for example, a material including a silicon oxide as a main component is used for the fixing substrate 130. For example, a material detachable by ultraviolet irradiation is used for the adhesive 340.

Next, as illustrated in FIG. 3, after a resist mask is formed on the back surface of the silicon substrate 100 by using the lithography method, a part of the silicon substrate 100 is etched by using a dry etching method. A first through hole 400 and a second through hole 410 are formed so that the device protecting insulating film 300 is exposed. After that, the resist mask is removed. Here, the first through hole 400 is laid out on the upper side of the piece of first connecting wiring 210 and the second through hole 410 is laid out on the upper side of the piece of second connecting wiring 220. The lithography method performs infrared alignment capable of aligning with a pattern formed on the main surface of the silicon substrate 100.

Note that, here, the resist mask is directly formed on the back surface of the silicon substrate 100. The resist mask may be formed after an insulating material, such as a silicon nitride film or a silicon oxide film, is formed on the back surface of the silicon substrate 100.

Next, as illustrated in FIG. 4, for example, aback surface insulating film 320 including, for example, a silicon oxide, is formed on the entire back surface of the silicon substrate 100 including inner walls of the first through hole 400 and the second through hole 410. Subsequently, the dry etching method performs entire surface etch back so as to remove the back surface insulating film 320 positioned on each of the bases of the first through hole 400 and the second through hole 410 and further remove the device protecting insulating film 300. Accordingly, a first opening 401 exposing a part of the piece of first connecting wiring 210, is formed. Here, since the dry etching method having large anisotropy is used to remove the back surface insulating film 320 and the device protecting insulating film 300, the back surface insulating film 320 formed on the inner wall of each of the first through hole 400 and the second through hole 410 can remain keeping its original thickness.

Next, as illustrated in FIG. 5, the dry etching method performs entire surface etch back so as to remove the wiring interlayer insulating film 310 positioned on the base of the second through hole 410. Accordingly, a second opening 411 exposing a part of the piece of second connecting wiring 220, is formed.

Next, as illustrated in FIG. 6, after the sputtering method is used so as to form a plated seed film, an electrolytic plating method is used so as to embed copper (Cu) inside each of the first opening 401 and the second opening 411. Subsequently, a chemical mechanical polishing (CMP) method is used so as to remove excessive copper (Cu) and an excessive plated seed film. As a result, a first through silicon via 230 electrically coupled to the piece of first connecting wiring 210 and a second through silicon via 240 electrically coupled to the piece of second connecting wiring 220 are formed.

Next, for example, ultraviolet rays are irradiated so as to detach the silicon substrate 100 including, for example, the semiconductor element and the piece of multilayer wiring formed thereon from the fixing substrate 130. Then, the silicon substrate 100 is moved and disposed on a dicing tape. Next, a dicing apparatus is used so as to dice the silicon substrate 100 including, for example, the semiconductor element and the piece of multilayer wiring formed thereon. The semiconductor device is competed.

Next, as illustrated in FIG. 7, for example, a flip-chip bonder is used and the semiconductor device is mounted on a chip mounting member 120 including a piece of metal wiring 204 formed thereon so that solder bumps 270, the first through silicon via 230, and the second through silicon via 240 are mutually electrically coupled.

As described above, according to the first embodiment, the first through silicon via 230 for propagating a signal, to be coupled to the piece of first connecting wiring 210 including the piece of lower layer wiring, can be formed on the main surface of the silicon substrate 100. The second through silicon via 240 for supplying a clock and for supplying a power source, to be coupled to the piece of second connecting wiring 220 including the piece of upper layer wiring, can be formed on the main surface of the silicon substrate 100. Accordingly, the semiconductor device that satisfies a low parasitic resistance and a large allowable current, can be achieved.

### Second Embodiment

A piece of first connecting wiring includes a plurality of pieces of metal wiring due to a limitation of a width of wiring. Therefore, in a case where a first opening that reaches the piece of first connecting wiring is formed on a silicon substrate, there is a problem that a wiring interlayer insulating film between the adjacent pieces of metal wiring is etched and then reliability of wiring decreases. According to a second embodiment, there is provided a technique capable of preventing the reliability of wiring from decreasing even when the wiring interlayer insulating film between the adjacent pieces of metal wiring is etched.

A semiconductor device according to the second embodiment is a semiconductor device capable of taking out electrical connection to the outside of a chip through each of through silicon vias directly coupled to a piece of upper layer wiring and a piece of lower layer wiring in the same chip. A point different from the above first embodiment is that the piece of first connecting wiring includes a two-layered piece of metal wiring.

### Structure of Through Silicon Via Included in Semiconductor Device and Method for Manufacturing the Structure

A method for manufacturing the semiconductor device according to the second embodiment will be sequentially described by following processes with reference to FIGS. 8 to 14. FIGS. 8 to 14 are cross-sectional views of main portions illustrating the method for manufacturing the semiconductor device.

First, as illustrated in FIG. 8, a device protecting insulating film 300 including, for example, a silicon oxide is formed on a main surface of a silicon substrate (at this stage, a flat and substantially circular shaped semiconductor thin plate referred to as a “semiconductor wafer”) 100. Subsequently, for example, a sputtering method, a lithography method, an etching method, or a CVD method, is used so as to form pieces of metal wiring 200, 201, 202, and 203, a piece of first connecting wiring (A) 210, a piece of first connecting wiring (B) 211, a piece of second connecting wiring 220, and a wiring interlayer insulating film 310.

Here, the piece of metal wiring 200 and the piece of first connecting wiring (A) 210 are formed of the same wiring layer (single layer). The piece of metal wiring 201 and the piece of first connecting wiring (B) 211 are formed of the same wiring layer (single layer). The pieces of metal wiring 202 and 203 and the piece of second connecting wiring 220 are formed of the same wiring layer (single layer). As illustrated in FIGS. 15 and 16 to be described layer, each of the piece of first connecting wiring (A) 210 and the piece of first connecting wiring (B) 211 includes a plurality of pieces of wiring formed and spaced apart from each other. The piece of second connecting wiring 220 is formed in a square region measuring 10 μm on a side in plan view.

The pieces of metal wiring 200, 201, 202, and 203, the piece of first connecting wiring (A) 210, the piece of first connecting wiring (B) 211, and the piece of second connecting wiring 220, include, for example, copper (Cu) as a main component. The wiring interlayer insulating film 310 includes, for example, a silicon oxide and an organic group-containing silicon oxide as main constituent materials. Copper (Cu) is lower than aluminum (Al) in terms of resistivity, and is effective in a method for reducing a wiring delay. The silicon substrate 100 is a substrate that has completed a so-called pre-process. An integrated circuit including, for example, a semiconductor element and a piece of wiring that couples the semiconductor element, are formed in a predetermined region on the main surface of the silicon substrate 100.

Note that, in FIG. 8, a part of a piece of multilayer wiring formed on the main surface of the silicon substrate 100 is only illustrated. For example, illustrations including a piece of wiring that is not directly related to the semiconductor element and the description, will be omitted. According to the second embodiment, a distance H between a base of the piece of first connecting wiring (A) 210 and a base of the piece of second connecting wiring 220 is set to be, for example, 2.0 μm.

Next, as illustrated in FIG. 9, after an adhesive 340 is formed on a fixing substrate 130, the fixing substrate 130 and the wiring interlayer insulating film 310 formed on the side of the main surface of the silicon substrate 100 adhere to each other through the adhesive 340. After that, by using, for example, a back grinding method or a dry polishing method, a back surface of the silicon substrate 100 (surface opposite to the main surface) is ground so as to thin a thickness of the silicon substrate 100 to 50 μm. Here, for example, a material including a silicon oxide as a main component is used for the fixing substrate 130. For example, a material detachable by ultraviolet irradiation is used for the adhesive 340.

Next, as illustrated in FIG. 10, after a resist mask is formed on the back surface of the silicon substrate 100 by using the lithography method, a part of the silicon substrate 100 is etched by using a dry etching method. A first through hole 400 and a second through hole 410 are formed so that the device protecting insulating film 300 is exposed. After that, the resist mask is removed. Here, the first through hole 400 is laid out on the upper side of the piece of first connecting wiring (A) 210 and the second through hole 410 is laid out on the upper side of the piece of second connecting wiring 220. The lithography method performs infrared alignment capable of aligning with a pattern formed on the main surface of the silicon substrate 100.

Note that, here, the resist mask is directly formed on the back surface of the silicon substrate 100. The resist mask may be formed after an insulating material, such as a silicon nitride film or a silicon oxide film, is formed on the back surface of the silicon substrate 100.

Next, as illustrated in FIG. 11, for example, a back surface insulating film 320 including, for example, a silicon oxide, is formed on the entire back surface of the silicon substrate 100 including inner walls of the first through hole 400 and the second through hole 410. Subsequently, the dry etching method performs entire surface etch back so as to remove the back surface insulating film 320 positioned on each of the bases of the first through hole 400 and the second through hole 410 and further remove the device protecting insulating film 300. Accordingly, a first opening 401 exposing a part of the piece of first connecting wiring (A) 210 and a part of the piece of second connecting wiring (B) 211, is formed.

Here, the piece of first connecting wiring (A) 210 includes a plurality of pieces of metal wiring disposed and spaced apart from each other. Accordingly, the wiring interlayer insulating film 310 between the adjacent pieces of metal wiring included in the first connecting wiring (A) 210 is etched by over-etching when the first opening 401 is formed. However, as illustrated in FIG. 16 to be described later, in plan view, a plurality of pieces of metal wiring included in the piece of second connecting wiring (B) 211 is disposed so as to alternate with the plurality of pieces of metal wiring included in the piece of first connecting wiring (A) 210. Thus, even when the wiring interlayer insulating film 310 between the adjacent pieces of metal wiring included in the piece of first connecting wiring (A) 210 is etched, the plurality of pieces of metal wiring included in the piece of second connecting wiring (B) 211 can prevent the over-etching.

Since the dry etching method having large anisotropy is used to remove the back surface insulating film 320 and the device protecting insulating film 300, the back surface insulating film 320 formed on the inner wall of each of the first through hole 400 and the second through hole 410 can remain keeping its original thickness.

Next, as illustrated in FIG. 12, the dry etching method performs entire surface etch back so as to remove the wiring interlayer insulating film 310 positioned on the base of the second through hole 410. Accordingly, a second opening 411 exposing a part of the piece of second connecting wiring 220, is formed.

Next, as illustrated in FIG. 13, after the sputtering method is used so as to form a plated seed film, an electrolytic plating method is used so as to embed copper (Cu) inside each of the first opening 401 and the second opening 411. Subsequently, a CMP method is used so as to remove excessive copper (Cu) and an excessive plated seed film. As a result, a first through silicon via 230 electrically coupled to the piece of first connecting wiring (A) 210 and a piece of first connecting wiring (B) 211, and a second through silicon via 240 electrically coupled to the piece of second connecting wiring 220, are formed.

Next, for example, ultraviolet rays are irradiated so as to detach the silicon substrate 100 including, for example, the semiconductor element and the piece of multilayer wiring formed thereon from the fixing substrate 130. Then, the silicon substrate 100 is moved and disposed on a dicing tape. Next, a dicing apparatus is used so as to dice the silicon substrate 100 including, for example, the semiconductor element and the piece of multilayer wiring formed thereon. The semiconductor device is competed.

Next, as illustrated in FIG. 14, for example, a flip-chip bonder is used and the semiconductor device is mounted on a chip mounting member 120 including a piece of metal wiring 204 formed thereon so that solder bumps 270, the first through silicon via 230, and the second through silicon via 240 are mutually electrically coupled.

### Characteristics of the Through Silicon Via Included in the Semiconductor Device

FIG. 15 is a partially enlarged cross-sectional view of a main portion illustrating the first connecting (A), the piece of first connecting wiring (B) , and the part of the first through silicon via.

The piece of first connecting wiring (A) includes pieces of metal wiring 250, 251, 252, and 253 in the same wiring layer. Each of the pieces of metal wiring 250, 251, 252, and 253 has a width of wiring defined as W1. The adjacent pieces of metal wiring 250, 251, 252, and 253 are spaced apart from each other with a distance defined as 51. Similarly, the piece of first connecting wiring (B) includes pieces of metal wiring 260, 261, and 262 in the same wiring layer. Each of the pieces of metal wiring 260, 261, and 262 has a width of wiring defined as W2. The adjacent pieces of metal wiring 260, 261, and 262 are spaced apart from each other with a distance defined as S2.

FIG. 16 is a partially enlarged plan view of a main portion illustrating the piece of first connecting wiring (A), the piece of first connecting wiring (B) , and a part of the first through silicon via. The above FIG. 15 corresponds to a cross-section illustrated by line A-A of FIG. 16

Each of the pieces of metal wiring 250, 251, 252, and 253 included in the piece of first connecting wiring (A) is formed so as to have the width of wiring W1 and extend in a Y direction. Each of the pieces of metal wiring 250, 251, 252, and 253 is formed so as to have a wiring interval S1 and be spaced apart from each other in parallel in a X direction perpendicular to the Y direction.

Each of the pieces of metal wiring 260, 261, and 262 included in the piece of first connecting wiring (B) is formed so as to have the width of wiring W2 and extend in the Y direction. Each of the pieces of metal wiring 260, 261, and 262 is formed so as to have a wiring interval S2 and be spaced apart from each other in parallel in the X direction.

According to the second embodiment, a center of the width of each of the pieces of metal wiring 260, 261, and 262 in the X direction corresponds to a center of the gap of each of the pieces of metal wiring 250, 251, 252, and 253 in the X direction.

The width of wiring W2 of each of the pieces of metal wiring 260, 261, and 262 is larger than the wiring interval S1 of each of the pieces of metal wiring 250, 251, 252, and 253. Furthermore, a center of the width of each of the pieces of metal wiring 251 and 252 in the X direction corresponds to a center of the gap of each of the pieces of metal wiring 260, 261, and 262. The width of wiring W1 of each of the pieces of metal wiring 251 and 252 is larger than the wiring interval S2 of each of the pieces of metal wiring 260, 261, and 262.

Accordingly, the inside of the first through silicon via 230 is covered with any of the pieces of metal wiring 250, 251, 252, and 253 included in the piece of first connecting wiring (A) or the pieces of metal wiring 260, 261, and 262 included in the piece of first connecting wiring (B). That is, in plan view, a region where the first through silicon via 230 is formed is completely covered with the piece of first connecting wiring (A) and the piece of first connecting wiring (B).

According to the second embodiment, based on a layout limitation of a forming process of the piece of metal wiring, the width of wiring W1 of each of the pieces of metal wiring 250, 251, 252, and 253, and the width of wiring W2 of each of the pieces of metal wiring 260, 261, and 262, are set to be, for example, 0.8 μm. The wiring interval S1 of each of the pieces of metal wiring 250, 251, 252, and 253, and the wiring interval S2 of the pieces of metal wiring 260, 261, and 262, are set to be, for example, 0.2 μm.

According to the second embodiment, the pieces of metal wiring 250, 251, 252, and 253 included in the piece of first connecting wiring (A) and the pieces of metal wiring 260, 261, and 262 included in the piece of first connecting wiring (B) are electrically coupled through connecting holes 520, 521, 522, 523, 524, and 525. In plan view, each of the connecting holes 520, 521, 522, 523, 524, and 525 is laid out so that the pieces of metal wiring 250, 251, 252, and 253 included in the piece of first connecting wiring (A) and the pieces of metal wiring 260, 261, and 262 included in the piece of first connecting wiring (B) overlap.

According to the second embodiment, the connecting holes 520, 521, 522, 523, 524, and 525 that couple the pieces of metal wiring 250, 251, 252, and 253 included in the first connecting wiring (A) and the pieces of metal wiring 260, 261, and 262 included in the first connecting wiring (B), are disposed outside the first through silicon via 230.

According to the second embodiment, a piece of circuit wiring 280 for coupling the first through silicon via 230 and a semiconductor element formed on a silicon substrate, is formed on the same wiring layer as the piece of first connecting wiring (A) is formed. For example, the piece of circuit wiring 280 is integrally formed with the piece of metal wiring 253 included in the piece of first connecting wiring (A).

In the semiconductor device manufactured as described above, a series resistance of the first through silicon via, the piece of first connecting wiring (A), and the piece of first connecting wiring (B) was evaluated by the Kelvin method.

FIG. 17 is a graphical representation of cumulative probability as a function of Kelvin resistance.

As illustrated in FIG. 17, a low resistance of approximately 0.11 Ω and a resistance distribution having small variation were obtained. A series resistance of the second through silicon via and the piece of second connecting wiring was evaluated by the Kelvin method. Similarly, a low resistance and a resistance distribution having small variation were obtained.

Next, a cross-sectional structure of a connecting portion of each of the first through silicon via, the piece of first connecting wiring (A), and the piece of first connecting wiring (B) was evaluated by a scanning electron microscope.

FIG. 18 is a photo illustrating the connecting portion of each of the first through silicon via, the piece of first connecting wiring (A), and the piece of first connecting wiring (B), taken by the scanning electron microscope.

As illustrated in FIG. 18, a thickness of the piece of first connecting wiring (A) 210 has decreased by the dry etching, but still remains. According to a shape of the first through silicon via 230, it can be seen that the wiring interlayer insulating film 310 present in a gap between the adjacent pieces of metal wiring included in the piece of first connecting wiring (A) 210 (regions illustrated with the wiring interval S1 in the above FIGS. 15 and 16) has been removed by the dry etching so as to reach the piece of first connecting wiring (B) 211. However, the piece of first connecting wiring (B) 211 remains with an almost perfect state. The etching has not reached the pieces of metal wiring 205 and 206 in the upper layer of the piece of first connecting wiring (B) 211. Thus, the pieces of metal wiring 205 and 206 in the upper layer of the piece of first connecting wiring (B) 211 can be used as normal pieces of circuit wiring.

As described above, according to the second embodiment, the first through silicon via 230 for propagating a signal, to be coupled to the piece of first connecting wiring (A) 210 and the piece of first connecting wiring (B) 211 including the lower layer wiring, can be formed on the main surface of the silicon substrate 100. The second through silicon via 240 for supplying a clock and for supplying a power source, to be coupled to the piece of second connecting wiring 220 including the upper layer, can be formed on the main surface of the silicon substrate 100. Accordingly, the semiconductor device that satisfies a low parasitic resistance and a large allowable current, can be achieved.

Furthermore, the two wiring layers including the piece of first connecting wiring (A) 210 and the piece of first connecting wiring (B) 211 perform electrical connection with the first through silicon via 230. In plan view, the pieces of metal wiring included in the piece of first connecting wiring (A) 210 and the pieces of metal wiring included in the piece of first connecting wiring (B) 211 are disposed so as to completely cover the region where the first through silicon via 230 is formed. Accordingly, degradation of reliability of wiring can be inhibited.

First modification to ten modification of the first and second embodiments will be described below.

### First Modification

According to the second embodiment, the width of wiring W1 of each of the pieces of metal wiring included in the piece of first connecting wiring (A) and the width of wiring W2 of each of the pieces of metal wiring included in the piece of first connecting wiring (B) are set to be 0.8 μm. The wiring interval S1 between the adjacent pieces of metal wiring included in the piece of first connecting wiring (A) and the wiring interval S2 between the adjacent pieces of metal wiring included in the piece of first connecting wiring (B) are set to be 0.2 μm. The widths of wiring W1 and W2 and the wiring intervals S1 and S2 are not limited to these.

Basically, the widths of wiring W1 and W2 and the wiring intervals S1 and S2 may be selected in accordance with a layout rule of the wiring layers in which the pieces of metal wiring included in the piece of first connecting wiring (A) and the pieces of metal wiring included in the piece of first connecting wiring (B) are formed. In an allowable range of the layout rule, the widths of wiring W1 and W2 are preferably as wide as possible and the wiring intervals S1 and S2 are preferably as narrow as possible.

Based on the widths of wiring W1 and W2 and the wiring intervals S1 and S2, in plan view, the number of the pieces of metal wiring included in the piece of first connecting wiring (A) and the number of the pieces of metal wiring included in the piece of first connecting wiring (B) are laid out so as to be numbers necessary for perfectly covering the first through silicon via.

In a case where the widths of wiring W1 and W2 and the wiring intervals S1 and S2 are constant, when a length of each of the pieces of metal wiring included in the piece of first connecting wiring (A) and a length of each of the pieces of metal wiring included in the piece of first connecting wiring (B) lengthen and the number of the pieces of metal wiring included in the piece of first connecting wiring (A) and the number of the pieces of metal wiring included in the piece of first connecting wiring (B) increase, the width (or depth) of each of the piece of first connecting wiring (A) and the piece of first connecting wiring (B) increases. Therefore, even when aligning accuracy of the first through silicon via is low, electrical connection can be securely performed. Meanwhile, there is a problem that a wiring area that can be used for circuit connection decreases and a parasitic capacitance of the first through silicon via increases as the width (or depth) of each of the piece of first connecting wiring (A) and the piece of first connecting wiring (B) increases. Therefore, the width (or depth) of each of the piece of first connecting wiring (A) and the piece of first connecting wiring (B) is preferably set to be substantially a size including an aligning margin plus the width (or depth) of the first through silicon via.

### Second Modification

According to the second embodiment, the center of the width of wiring W1 of each of the pieces of metal wiring included in the piece of first connecting wiring (A) and the center of the wiring interval S2 between the adjacent pieces of metal wiring included in the piece of first connecting wiring (B) are laid out so as to correspond to each other. The center of the width of wiring W2 of each of the pieces of metal wiring included in the piece of first connecting wiring (B) and the wiring interval S1 between the adjacent pieces of metal wiring included in the piece of first connecting wiring (A) are laid out so as to correspond to each other. However, they do not necessarily correspond to each other.

A pattern formed by a disjunction of the width of wiring W1 of each of the pieces of metal wiring included in the piece of first connecting wiring (A) and the width of wiring W2 of each of the pieces of metal wiring included in the piece of first connecting wiring (B) may completely cover the first through silicon via in plan view. However, since the pieces of metal wiring included in the piece of first connecting wiring (A) and the pieces of metal wiring included in the piece of first connecting wiring (B) need to be electrically coupled to each other by the connecting holes, they need to have aligning margins necessary for forming the connecting holes so as to be overlapped each other.

### Third Modification

According to the second embodiment, in plan view, the connecting holes that couple the pieces of metal wiring included in the piece of first connecting wiring (A) and the pieces of metal wiring included in the piece of first connecting wiring (B) are laid out outside the first through silicon via. They can be also laid out inside the first through silicon via in plan view. In this case, since the total number of the connecting holes can increase, a decrease of a parasitic resistance can be achieved. However, in a case where the first opening in which the first through silicon via is embedded is formed, when the pieces of metal wiring included in the piece of first connecting wiring (A) have been completely etched, a protruding step is formed in the wiring interlayer insulating film. Therefore, when a conductive material is embedded in the first opening, degradation of reliability of wiring may occur.

### Fourth Modification

According to the second embodiment, the two wiring layers including the piece of first connecting wiring (A) and the piece of first connecting wiring (B) perform the electrical connection with the first through silicon via. Three wiring layers or more can be used. As the distance between the base of the piece of first connecting wiring (A) including the lower layer wiring and the base of the piece of second connecting wiring including the upper layer wiring, 2.0 μm is exemplified (distance H illustrated in the above FIG. 8). The pieces of wiring with a different distance can be used if necessary.

In a case where etching selectivity of a metal material of the pieces of metal wiring included in the piece of first connecting wiring (A) to an insulating material included in the wiring interlayer insulating film (etching speed of the insulating material/etching speed of the metal material) is defined as α, when a relationship in which a total thickness of each of the pieces of metal wiring included in the piece of first connecting wiring (A) in an etching direction is larger than H/αis satisfied, the number of wiring layers used for the piece of first connecting wiring (A) and the distance between the base of the piece of first connecting wiring (A) and the base of the piece of second connecting wiring can be changed.

That can be also said regarding the distance between the base of the piece of first connecting wiring including the lower layer wiring and the base of the piece of second connecting wiring including the upper layer wiring (distance H illustrated in the above FIG. 1) according to the first embodiment.

### Fifth Modification

According to the second embodiment, in order to couple the first through silicon via to the semiconductor element, the piece of circuit wiring is coupled to the piece of metal wiring at the outermost position of the piece of first connecting wiring (A). The piece of circuit wiring may be coupled to another piece of metal wiring included in the piece of first connecting wiring (A) or can be coupled to a piece of metal wiring included in the piece of first connecting wiring (B).

In a case where the piece of circuit wiring is coupled to the silicon substrate, coupling the piece of circuit wiring to the piece of first connecting wiring (A) close to the silicon substrate can effectively use a wiring resource.

### Sixth Modification

According to the first and second embodiments, as the piece of second connecting wiring, the piece of metal wiring having a single-layered square measuring 10 μm on a side is used. The piece of second wiring is not limited to the form.

Basically, it is necessary to follow a layout rule of the wiring layer in which the piece of second connecting wiring is disposed. When allowed by the layout rule, a single-layered wiring layer preferably perfectly covers the second through silicon via plus an aligning margin. In a case where two wiring layers or more cover the second through silicon via, for example, in accordance with the method for laying out the piece of first connecting wiring (A) and the piece of first connecting wiring (B) according to the second embodiment, a piece of metal wiring in each of the wiring layers included in the piece of second connecting wiring is individually laid out. That is, using the two wiring layers or more, in a region where the second through silicon via is formed, a pattern formed by a disjunction of a width of wiring of the piece of metal wiring in each of the wiring layers included in the second connecting wiring may perfectly cover the second through silicon via in plan view.

### Seventh Modification

According to the second embodiment, a square is used for the shape of the first through silicon via in plan view. Shapes other than the square may be used. For example, a rectangle, a hexagon, an octagon, or a circle may be used. The first through silicon via and the second through silicon via do not necessarily the same shape. For example, the second through silicon via directly coupled to the piece of second connecting wiring supplies a clock and a power source. Therefore, the width of the second through silicon via (diameter) can also increase for a low resistance.

### Eighth Modification

In order to improve flatness of a piece of metal wiring, a dummy metal in an electrically floating state is often formed in a region between adjacent pieces of metal wiring. However, when the first through silicon via and the second through silicon via are etched, the dummy metal becomes an etching barrier. Therefore, the dummy metal is preferably not formed in the region where the first through silicon via and the second through silicon via are formed.

### Ninth Modification

According to the first and second embodiments, the silicon substrate including the semiconductor element formed thereon is temporarily fixed to the fixing substrate including a silicon oxide by the adhesive. The present invention is not limited to this. For example, the fixing substrate may be a silicon substrate and, as an adhesive, a resin for fixing permanently, such as a polyimide, can be used.

### Tenth Modification

According to the first and second embodiments, the single-layered semiconductor device is laminated on the chip mounting member in a state where the main surface including the semiconductor element formed thereon faces up (Face-up state). Other layered forms can be used. The number of lamination layers may be two or more. Lamination may be performed in a case where the main surface including the semiconductor element formed thereon faces down (Face-down state) if necessary.

The present invention made by the present inventors has been specifically described based on the embodiments. The present invention is not limited to the above embodiments. Needless to say, various alternations may be made without departing from the spirit.

### REFERENCE SIGNS LIST

100 silicon substrate

120 chip mounting member

130 fixing substrate

200, 201, 202, 203, 204, 205, 206 metal wiring

210 first connecting wiring, first connecting wiring (A)

211 first connecting wiring (B)

220 second connecting wiring

230 first through silicon via

240 second through silicon via

250, 251, 252, 253 metal wiring

260, 261, 262 metal wiring

270 solder bump

280 circuit wiring

300 device protecting insulating film

310 wiring interlayer insulating film

320 back surface insulating film

340 adhesive

400, 401 first opening

400A first through hole

410A second through hole

410,411 second opening

520, 521, 522, 523, 524, 525 connecting hole

H distance

S1, S2 wiring interval

W1, W2 width of wiring

1. A semiconductor device comprising:
a substrate having a first surface and a second surface opposite to the first surface;
a semiconductor element formed on the first surface of the substrate;
a protecting insulating film for covering the semiconductor element;
a piece of multilayer wiring including a plurality of wiring layers formed on the protecting insulating film;
a piece of first connecting wiring including a first part of the wiring layers in the piece of multilayer wiring; and
a piece of second connecting wiring including a second part of the wiring layers in the piece of multilayer wiring,
wherein
a lowermost wiring layer included in the piece of second connecting wiring is formed of a wiring layer upper than a lowermost wiring layer included in the piece of first connecting wiring,
a first through electrode that passes through and is formed in the substrate in a first region in plan view is coupled to the piece of first connecting wiring,
a second through electrode that passes through and is formed in the substrate in a second region different from the first region in plan view is coupled to the pieces of second connecting wiring,
the piece of first connecting wiring includes the first through electrode in plan view, and
the piece of second connecting wiring includes the second through electrode in plan view.

2. The semiconductor device according to claim 1, wherein a distance from the first surface of the substrate to the lowermost wiring layer included in the piece of second connecting wiring is longer than a distance from the first surface of the substrate to the lowermost wiring layer included in the piece of first connecting wiring.

3. The semiconductor device according to claim 1, wherein the piece of first connecting wiring includes two wiring layers or more disposed through an insulating film, and each of the two wiring layers or more included in the piece of first connecting wiring includes a plurality of pieces of metal wiring disposed and spaced apart from each other.

4. The semiconductor device according to claim 1, wherein
the piece of first connecting wiring includes a plurality of pieces of first metal wiring positioned in a lower layer disposed through an insulating film and a plurality of pieces of second metal wiring positioned in an upper layer disposed through the insulating film,
the plurality of pieces of first metal wiring is spaced apart from each other in a first direction and extends in a second direction perpendicular to the first direction,
the plurality of pieces of second metal wiring is spaced apart from each other in the first direction and extends in the second direction,
the piece of first metal wiring includes a gap between the adjacent pieces of second metal wiring in the first direction in plan view, and
the piece of second metal wiring includes a gap between the adjacent pieces of first metal wiring in the first direction in plan view.

5. The semiconductor device according to claim 1, wherein
in a case where a distance between a base of the lowermost wiring layer including in the piece of first connecting wiring and a base of the lowermost wiring layer included in the piece of second connecting wiring is defined as H, and
in a case where etching selectivity of the wiring layer included in the piece of first connecting wiring to an insulating film formed between the piece of the first connecting wiring and the piece of second connecting wiring is defined as α,
a total thickness of the wiring layer included in the first connecting wiring is larger than H/α.

6. The semiconductor device according to claim 5, wherein
the insulating film includes a silicon oxide and an organic matter-containing silicon oxide as main constituent materials, and
the wiring layer included in the piece of first connecting wiring includes copper as a main component.

7. The semiconductor device according to claim 1, wherein the piece of first connecting wiring, the first through electrode, and the second through electrode include copper.

8. The semiconductor device according to claim 1, wherein
the first through electrode is used for propagating a signal, and
the second through electrode is used for supplying a clock or a power source.

9. A method for manufacturing a semiconductor device, comprising the steps of:
(a) preparing a substrate having a first surface and a second surface opposite to the first surface;
(b) forming a protecting insulating film for covering a semiconductor element after the semiconductor element is formed on the first surface of the substrate;
(c) forming a piece of multilayer wiring including a plurality of wiring layers on the protecting insulating film, forming a piece of first connecting wiring using a first part of the wiring layers in the piece of multilayer wiring, and forming a piece of second connecting wiring including, as a lowermost layer, a wiring layer upper than a lowermost wiring layer included in the piece of first connecting wiring, using a second part of the wiring layers;
(d) processing a thickness of the substrate to be thin from the second surface after the step (c);
(e) forming a first through hole that passes through the substrate from a side of the second surface of the substrate, in a first region included in a region in which the piece of the first connecting wiring is projected onto the substrate, and forming a second through hole that passes through the substrate from a side of the second surface of the substrate, in a second region included in a region in which the piece of second connecting wiring is projected onto the substrate, after the step (d);
(f) forming a back surface insulating film on the entire second surface of the substrate to cover an inner wall of each of the first through hole and the second through hole after the step (e);
(g) etching a base of the first through hole and a base of the second through hole, simultaneously, and forming a first opening that reaches the pieces of first connecting wiring after the step (f);
(h) etching the base of the second through hole, and forming a second opening that reaches the piece of second connecting wiring after the step (g); and
(i) forming a first through electrode inside the first opening, and forming a second through electrode inside the second opening after the step (h).

10. The method for manufacturing a semiconductor device according to claim 9, wherein
the piece of first connecting wiring includes two wiring layers or more disposed through an insulating film, and
each of the two wiring layers or more included in the piece of first connecting wiring includes a plurality of pieces of metal wiring disposed and spaced apart from each other.

11. The method for manufacturing a semiconductor device according to claim 9, wherein
the piece of first connecting wiring includes a plurality of pieces of first metal wiring positioned in a lower layer disposed through an insulating film and a plurality of pieces of second metal wiring positioned in an upper layer disposed through the insulating film,
the plurality of pieces of first metal wiring is spaced apart from each other in a first direction and extends in a second direction perpendicular to the first direction,
the plurality of pieces of second metal wiring is spaced apart from each other in the first direction and extends in the second direction,
the piece of first metal wiring includes a gap between the adjacent pieces of second metal wiring in the first direction in plan view, and
the piece of second metal wiring includes a gap between the adjacent pieces of first metal wiring in the first direction in plan view.

12. The method for manufacturing a semiconductor device according to claim 9, wherein
in a case where a distance between a base of the lowermost wring layer included in the piece of first connecting wiring and a base of the lowermost wiring layer included in the piece of second connecting wiring is defined as H, and
in a case where etching selectivity of the wiring layer included in the piece of first connecting wiring to an insulating film formed between the piece of first connecting wiring and the piece of second connecting wiring is defined as α,
a total thickness of the wiring layer included in the piece of first connecting wiring is larger than H/α.

13. The method for manufacturing a semiconductor device according to claim 12, wherein
the insulating film includes a silicon oxide and an organic matter-containing silicon oxide as main constituent materials, and
the wiring layer included in the piece of first connecting wiring includes copper as a main component.

14. The method for manufacturing a semiconductor device according to claim 9, wherein the piece of first connecting wiring, the first through electrode, and the second through electrode include copper.

15. The method for manufacturing a semiconductor device according to claim 9, wherein
the first through electrode is used for propagating a signal, and
the second through electrode is used for supplying a clock or a power source.
